(19) United States
(12) Patent Application Publication
(10) Pub. No.: US 2025/0343042 A1
(43) Pub. Date: Nov. 6, 2025

(54) DIFFUSING AGENT COMPOSITION, AND METHOD FOR MANUFACTURING SEMICONDUCTOR SUBSTRATE

(71) Applicant: TOKYO OHKA KOGYO CO., LTD., Kawasaki-shi (JP)

(72) Inventors: Keisuke KUBO, Kawasaki-shi (JP); Akito NISHIZAWA, Kawasaki-shi (JP)

(21) Appl. No.: 18/866,721

(22) PCT Filed: Jun. 2, 2023
(86) PCT No.: PCT/JP2023/020663

§ 371 Date: Nov. 18, 2024

(30) Foreign Application Priority Data
Jun. 7, 2022 (JP) 2022-092245

(51) Int. Cl. H01L 21/225; C23C 8/42

(52) U.S. Cl. CPC H01L 21/225; C23C 8/42

(57) ABSTRACT

A diffusing agent composition capable of preventing generation of foreign matter in a coating film to be formed, and a method for manufacturing a semiconductor substrate using the diffusing agent composition. The diffusing agent composition includes an impurity diffusing component; and a solvent, in which a content of the impurity diffusing component is more than 0% by mass and 1.0% by mass or less, the solvent (S) includes a first solvent and a second solvent different from the first solvent, a boiling point of the first solvent under atmospheric pressure is 180° C. or higher, a hydrogen bonding force term δH of a Hansen solubility parameter of the first solvent is 14.0 or more, and a content of the first solvent is more than 0.10% by mass with respect to a mass of the solvent.

### TECHNICAL FIELD

The present invention relates to a diffusing agent composition for use in diffusing an impurity diffusing component into a semiconductor substrate, and a method for manufacturing a semiconductor substrate using the diffusing agent composition.

### BACKGROUND ART

Semiconductor substrates used in semiconductor elements such as a transistor, a diode and a solar battery are manufactured by diffusing, into the semiconductor substrates, impurity diffusing components such as phosphorus, boron, and arsenic. As a method of diffusing an impurity diffusing component in a semiconductor substrate, there is a method of applying a diffusing agent composition containing an impurity diffusing component to the semiconductor substrate. For example, as a method of doping silicon, there is a method in which a diffusing agent composition is applied to a surface of a silicon substrate to diffuse an impurity (phosphorus, boron, or arsenic), the diffusing agent composition containing an impurity diffusing component such as a phosphorus compound, a boron compound, or an arsenic compound and a solvent such as propylene glycol monomethyl ether acetate or propylene glycol monomethyl ether (see, for example, Patent Document 1).

### CITATION LIST

### Patent Document

Patent Document 1: Japanese Unexamined Patent Application, Publication No. 2020-194827

### DISCLOSURE OF THE INVENTION

### Problems to be Solved by the Invention

However, in the case where the diffusing agent composition containing the impurity diffusing component such as a phosphorus compound, a boron compound, or an arsenic compound and the solvent such as propylene glycol monomethyl ether acetate or propylene glycol monomethyl ether is applied to diffuse the impurity as described in Patent Document 1, a large amount of foreign matter (defects) may be generated in a coating film to be formed. Since the presence of a large amount of foreign matter may adversely affect semiconductor elements, it is desired to prevent the generation of foreign matter.

The present invention has been made in view of the above problem, and an object thereof is to provide a diffusing agent composition capable of preventing generation of foreign matter in a coating film to be formed, and a method for manufacturing a semiconductor substrate using the diffusing agent composition.

### Means for Solving the Problems

The present inventors have found that the above problem can be solved by a diffusing agent composition including an impurity diffusing component (A) and a solvent (S), in which a content of the impurity diffusing component (A) is more than 0% by mass and 1.0% by mass or less, the solvent (S) includes a solvent (S1) and a solvent (S2) different from the solvent (S1), a boiling point of the solvent (S1) under atmospheric pressure is 180° C. or higher, a hydrogen bonding force term δH of a Hansen solubility parameter of the solvent (S1) is 14.0 or more, and a content of the solvent (S1) is more than 0.10% by mass with respect to a mass of the solvent (S), and have completed the present invention. More specifically, the present invention provides the following.

[1] A diffusing agent composition for use in diffusing an impurity into a semiconductor substrate, the diffusing agent composition including:
an impurity diffusing component (A); and a solvent (S),
a content of the impurity diffusing component (A) being more than 0% by mass and 1.0% by mass or less,
the solvent (S) including a solvent (S1) and a solvent (S2) different from the solvent (S1),
a boiling point of the solvent (S1) under atmospheric pressure being 180° C. or higher,
a hydrogen bonding force term δH of a Hansen solubility parameter of the solvent (S1) being 14.0 or more,
a content of the solvent (S1) being more than 0.10% by mass with respect to a mass of the solvent (S).

[2] The diffusing agent composition as described in [1], in which the impurity diffusing component (A) is 60% by mass or more with respect to a total solid content in the diffusing agent composition.

[3] The diffusing agent composition as described in [1] or [2], in which the content of the solvent (S1) is less than 30% by mass with respect to the mass of the solvent (S).

[4] The diffusing agent composition as described in any one of [1] to [3], in which the solvent (S1) is a glycol-based solvent.

[5] The diffusing agent composition as described in any one of [1] to [4], in which the impurity diffusing component (A) contains a compound having the hydrogen bonding force term δH of the Hansen solubility parameter of 60.0 or more.

[6] The diffusing agent composition as described in any one of [1] to [5], further including an amine compound (B).

[7] A method for manufacturing a semiconductor substrate, the method including: forming a coating film by applying the diffusing agent composition as described in any one of [1] to [6] on the semiconductor substrate; and
diffusing the impurity diffusing component (A) in the diffusing agent composition into the semiconductor substrate.

[8] The method for manufacturing a semiconductor substrate as described in [7], in which the coating film is heated to diffuse the impurity diffusing component (A) into the semiconductor substrate.

### Effects of the Invention

According to the present invention, it is possible to provide a diffusing agent composition capable of preventing generation of foreign matter in a coating film to be formed, and a method for manufacturing a semiconductor substrate using the diffusing agent composition.

### PREFEFRED MODE FOR CARRYING OUT THE INVENTION

### <<Diffusing Agent Composition>>

A diffusing agent composition is a diffusing agent composition which is used for diffusion of an impurity into a semiconductor substrate, and includes an impurity diffusing component (A) and a solvent (S). A content of the impurity diffusing component (A) is more than 0% by mass and 1.0% by mass or less. The solvent (S) includes a solvent (S1) and a solvent (S2) different from the solvent (S1). A boiling point of the solvent (S1) under atmospheric pressure is 180° C. or higher, and a hydrogen bonding force term δH of a Hansen solubility parameter of the solvent (S1) is 14.0 or more. A content of the solvent (S1) is more than 0.10% by mass with respect to a mass of the solvent (S). By using such a diffusing agent composition, a coating film in which generation of foreign matter is prevented can be formed. Essential or optional components included in the diffusing agent composition will be described below.

### [Impurity Diffusing Component (A)]

The impurity diffusing component (A) contained in the diffusing agent composition is a component which is conventionally used for doping of a semiconductor substrate, and may be an n-type dopant or a p-type dopant. Examples of the n-type dopant include simple substances such as phosphorus and arsenic and compounds including these elements. Examples of the p-type dopant include simple substances such as boron and compounds including these elements. The impurity diffusing component (A) preferably contains a compound having a high hydrogen bonding force term δH of the Hansen solubility parameter, for example, a compound having δH of 14.0 or more, more preferably a compound having δH of 25.0 or more, still more preferably a compound having δH of 40.0 or more, and particularly preferably a compound having δH of 60.0 or more. The impurity diffusing component (A) preferably contains a compound having δH of 90.0 or less. If δH is in the above range, diffusion performance can be sufficiently exhibited. Details of the Hansen solubility parameter will be described later.

As the impurity diffusing component (A), a phosphorus compound, a boron compound or an arsenic compound is preferable because they are easily available and are easy to handle. Examples of the phosphorus compound include phosphoric acid (δH: 62.6) and a phosphate ester. Examples of the phosphate ester include monoisopropyl phosphate (δH: 29.3) and diisopropyl phosphate (δH: 14.0). Examples of the boron compound include boric acid (δH: 60.9) and diboron trioxide (δH: 15.0). The diboron trioxide becomes the boric acid when dissolved in water. Examples of the arsenic compound include arsenic acid and trialkyl arsenite. Examples of the trialkyl arsenite include tributyl arsenite.

The content of the impurity diffusing component (A) in the diffusing agent composition is more than 0% by mass and 1.0% by mass or less, preferably 0.01% by mass or more and 0.5% by mass or less, and more preferably 0.05% by mass or more and 0.1% by mass or less.

The content of the impurity diffusing component (A) is preferably 60% by mass or more, more preferably 80% by mass or more, still more preferably 90% by mass or more, particularly preferably 95% by mass or more with respect to a total solid content in the diffusing agent composition. In a case where the content of the impurity diffusing component (A) is less than 60% by mass with respect to the total solid content in the diffusing agent composition, when compared at the same film thickness, the content of the impurity diffusing component (A) decreases, and a diffusion amount of the impurity diffusing component (A) decreases, so that it tends to be difficult to obtain a required diffusion amount.

### [Amine Compound (B)]

The diffusing agent composition preferably contains an amine compound (B). The amine compound (B) is an aliphatic amine. Here, it is assumed that an amine compound which does not include an aromatic group is the aliphatic amine. In the amine compound (B), when the number of primary amino groups included in the amine compound (B) is NA, the number of secondary amino groups included in the amine compound (B) is NB and the number of tertiary amino groups included in the amine compound (B) is NC, NA, NB and NC satisfy formulas (1) and (2) below:

$$( NB + NC ) \geq 1 ; and \qquad ( 1 )$$

$$( NA + NB + NC ) \geq 2. \qquad ( 2 )$$

The diffusing agent composition includes, together with the impurity diffusing component (A), the amine compound (B) which satisfies the predetermined conditions described above, and thus it is possible to use the diffusing agent composition so as to form a thin film which is excellent in stability over time.

When NB+NC<NA, in the amine compound (B), the primary amino groups are bound to an aliphatic hydrocarbon group having 2 or less carbon atoms. When a primary amino group having a low steric hindrance is bound to an aliphatic hydrocarbon group having a relatively long chain, the three-dimensional flexibility of the primary amino group is high. When NB+NC<NA, the amine compound includes two or more primary amino groups. Although the detailed reason is unclear, it is considered that the conditions described above are satisfied in the primary amino groups, and thus the number of primary amino groups having high three-dimensional flexibility is limited so as to enhance the formation of the film and the stability of the film.

The amine compound (B) may be a linear or branched aliphatic amine or may be an aliphatic amine having a cyclic skeleton. Since a desired effect produced by use of the amine compound (B) is easily obtained, the amine compound (B) is preferably a linear or branched aliphatic amine compound.

The amine compound (B) may include a carbon-carbon unsaturated bond. In terms of, for example, the stability of the diffusing agent composition, the amine compound (B) preferably does not include a carbon-carbon unsaturated bond.

As the amine compound (B), an amine compound is preferable which satisfies the conditions described above on NA, NB and NC and which is represented by formula (B1) below.

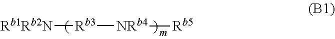

In formula (B1), R^{b1}, R^{b2}, R^{b4} and R^{b5} each independently represent a hydrogen atom, an alkyl group having 1 or more and 6 or less carbon atoms or a hydroxyalkyl group having 1 or more and 6 or less carbon atoms. R^{b3} represents an alkylene group having 1 or more and 6 or less carbon atoms. Here, m represents an integer of 1 or more and 5 or less, and m preferably represents an integer of 1 or more and 3 or less. When m represents an integer of 2 or more and 5 or less, a plurality of R^{b3}s may be identical or different, and a plurality of R^{b4}s may be identical or different. In formula (B1), any two groups selected from the group consisting of R^{b1}, R^{b2}, R^{b4} and R^{b5} may be bound to form a ring. The amine compound represented by formula (B1) may include two rings.

The number of carbon atoms in the alkyl group serving as R^{b1}, R^{b2}, R^{b4} and R^{b5} is 1 or more and 6 or less, and is preferably 1 or more and 4 or less. Specific examples of the alkyl group serving as R^{b1}, R^{b2}, R^{b4} and R^{b5} include a methyl group, an ethyl group, an n-propyl group, an isopropyl group, an n-butyl group, an isobutyl group, a sec-butyl group, a tert-butyl group, an n-pentyl group and an n-hexyl group. Among them, a methyl group, an ethyl group, an n-propyl group, an isopropyl group, an n-butyl group, an isobutyl group, a sec-butyl group and a tert-butyl group are preferable.

The number of carbon atoms in the hydroxyalkyl group serving as R^{b1}, R^{b2}, R^{b4} and R^{b5} is 1 or more and 6 or less, and is preferably 1 or more and 4 or less. Specific examples of the hydroxyalkyl group serving as R^{b1}, R^{b2}, R^{b4} and R^{b5} include a hydroxymethyl group (methylol group), a 2-hydroxyethyl group, a 3-hydroxy-n-propyl group, a 4-hydroxy-n-butyl group, a 5-hydroxy-n-pentyl group and a 6-hydroxy-n-hexyl group. Among them, a 2-hydroxyethyl group and a 3-hydroxy-n-propyl group are preferable.

The number of carbon atoms in the alkylene group serving as R^{b3} is 1 or more and 6 or less, and is preferably 1 or more and 4 or less. Specific examples of the alkylene group serving as R^{b3} include a methylene group, an ethane-1,2-diyl group, an ethane-1,1-diyl group, a propane-1,3-diyl group, a propane-1,2-diyl group, a propane-1,1-diyl group, a butane-1,4-diyl group, a pentane-1,5-diyl group and a hexane-1,6-diyl group. Among them, a methylene group, an ethane-1,2-diyl group and a propane-1,3-diyl group are preferable.

Specific preferred examples of the amine compound (B) include: N-alkylalkanediamines such as N-methylethylenediamine, N-ethylethylenediamine, N-n-propylethylenediamine, N-isopzopylethylenediamine, N-n-butylethylenediamine, N-isobutylethylenediamine, N-sec-butylethylenediamine, N-tert-butylethylenediamine, N-methyl-1,3-propanediamine, N-ethyl-1,3-propanediamine, N-n-propyl-1,3-propanediamine, N-isopropyl-1,3-propanediamine, N-n-butyl-1,3-propanediamine, N-isobutyl-1,3-propanediamine, N-sec-butyl-1,3-propanediamine and N-tert-butyl-1,3-propanediamine;
N,N-dialkylalkanediamines such as N,N-dimethylethylenediamine, N,N-diethylethylenediamine, N,N-di-n-propylethylenediamine, N,N-diisopropylethylenediamine, N,N-di-n-butylethylenediamine, N,N-diisobutylethylenediamine, N,N-di-sec-butylethylenediamine, N,N-di-tert-butylethylenediamine, N,N-dimethyl-1,3-propanediamine, N,N-diethyl-1,3-propanediamine, N,N-di-n-propyl-1,3-propanediamine, N,N-diisopropyl-1,3-propanediamine, N,N-di-n-butyl-1,3-propanediamine, N,N-diisobutyl-1,3-propanediamine, N,N-di-sec-butyl-1,3-propanediamine and N,N-di-tert-butyl-1,3-propanediamine; N,N′-dialkylalkanediamines such as N,N′-dimethylethylenediamine, N,N′-diethylethylenediamine, N,N′-di-n-propylethylenediamine, N,N′-diisopropylethylenediamine, N,N′-di-n-butylethylenediaminie, N,N′-diisobutylethylenediamine, N,N′-di-sec-butylethylenediamine, N,N′-di-tert-butylethylenediamine, N,N′-dimethyl-1,3-propanediamine, N,N′-diethyl-1,3-propanediamine, N,N′-di-n-propyl-1,3-propanediamine, N,N′-diisopropyl-1,3-propanediamine, N,N′-di-n-butyl-1,3-propanediamine, N,N′-diisobutyl-1,3-propanediamine, N,N′-di-sec-butyl-1,3-propanediamine and N,N′-di-tert-butyl-1,3-propanediamine;
aliphatic amines having 3 or more nitrogen atoms such as diethylenetriamine, triethylenetetramine, tetraethylenepentamine, 3,3-diaminodipropylamine, N,N′-bis (3-aminopropyl) ethylenediamine, N,N′-bis(3-aminopropyl)-1,3-propanediamine, tris (2-aminoethyl) amine, tris (3-aminopropyl) amine, N-(2-aminoethyl) piperazine and N-(3-aminopropyl) piperazine;
hydroxyalkylamines such as N-(2-aminoethyl) ethanolamine, N,N-bis(2-aminoethyl) ethanolamine, N,N-bis(2-hydroxyethyl) ethylenediamine, N-(3-aminopropyl) ethanolamine, N,N-bis(3-aminopropyl) ethanolamine and N,N-bis(2-hydroxyethyl)-1,3-propanediamine; and
aliphatic diamines having a cyclic skeleton such as piperazine, N-methylpiperazine and N-ethylpiperazine.

The amine compound (B) may be used alone or in combination of two or more types thereof.

The content of the amine compound (B) in the diffusing agent composition is not particularly limited as long as the desired effect produced by use of the amine compound (B) is obtained. The content of the amine compound (B) in the diffusing agent composition is preferably 0.01% by mass or more and 20% by mass or less, more preferably 0.02% by mass or more and 5% by mass or less and particularly preferably 0.03% by mass or more and 1% by mass or less. When the amount of amine compound (B) within the above range is used, the unevenness of the film caused by the generation of particles or the like and the deterioration of quality of the film caused by the precipitation of the amine are easily reduced.

### [Solvent (S)]

The diffusing agent composition contains a solvent (S). The solvent (S) includes a solvent (S) and a solvent (S2) different from the solvent (S1).

The solvent (S1) has a boiling point under atmospheric pressure (boiling point at 1 atm) of 180° C. or higher and the hydrogen bonding force term δH of the Hansen solubility parameter of 14.0 or more. The solvent (S1) may be one type or two or more types. The solvent (S1) is an organic solvent.

The boiling point of the solvent (S1) under atmospheric pressure is 180° C. or higher, preferably 195° C. or higher, more preferably 230° C. or higher, and still more preferably 240° C. or higher. The boiling point of the solvent (S1) under atmospheric pressure is preferably 400° C. or lower, and more preferably 300° C. or lower.

The hydrogen bonding force term δH of the Hansen solubility parameter of the solvent (S1) is 14.0 or more, and preferably 18.0 or more. The hydrogen bonding force term δH of the Hansen solubility parameter of the solvent (S1) is preferably 40.0 or less, more preferably 30.0 or less, and still more preferably 20.0 or less.

The Hansen solubility parameter is a value used for predicting the solubility of a substance, and is described in detail, for example, in “Hansen Solubility Parameters: A User's Handbook” (CPC Press, 2007) by Charles M. Hansen and “The CRC Handbook and Solubility Parameters and Cohesion Parameters” edited by Allan F. M. Barton (1999). The hydrogen bonding force term δH of the Hansen solubility parameter (hereinafter also referred to simply as “δH”) can be determined using software developed by Charles Hansen et al. (software name: Hansen Solubility Parameter in Practice (HSPiP)).

Examples of the solvent (S1) include glycol-based solvents such as ethylene glycol (boiling point 198° C., δH: 26.0), 1,5-pentanediol (boiling point 239° C., δH: 18.9), diethylene glycol (boiling point 245° C., δH: 19.0), 1,3-butanediol (boiling point 207° C., δH: 20.9), 1,4-butanediol (boiling point 228° C., δH: 20.9), propylene glycol (boiling point 188° C., δH: 21.3), and triethylene glycol (boiling point 244° C., δH: 18.6). The boiling point is a boiling point under atmospheric pressure.

The solvent (S2) is different from the solvent (S1). That is, the solvent (S2) is a solvent which does not correspond to the solvent (S1), and is a solvent having a boiling point under atmospheric pressure of lower than 180° C. and a hydrogen bonding force term δH of the Hansen solubility parameter of less than 14.0, a solvent having a boiling point under atmospheric pressure of lower than 180° C. and a hydrogen bonding force term δH of the Hansen solubility parameter of 14.0 or more, or a solvent having a bailing point under atmospheric pressure of 180° C. or higher and a hydrogen bonding force term δH of the Hansen solubility parameter of less than 14.0. The solvent (S2) may be one type or two or more types. The solvent (S2) is an organic solvent or water.

The boiling point of the solvent (S2) under atmospheric pressure is preferably 150° C. or lower, and more preferably 150° C. or lower. The boiling point of the solvent (S1) under atmospheric pressure is preferably 100° C. or higher, and more preferably 110° C. or higher.

The hydrogen bonding force term δH of the Hansen solubility parameter of the solvent (S2) is preferably 13.0 or less, and more preferably 12.0 or less. The hydrogen bonding force term δH of the Hansen solubility parameter of the solvent (S2) is preferably 7.0 or more, and more preferably 9.0 or more.

Examples of the solvent (S2) include alkylene glycol monoalkyl ethers such as propylene glycol monomethyl ether (PGME) (boiling point 121° C., δH: 11.6) and alkylene glycol monoalkyl ether acetates such as propylene glycol monomethyl ether acetate (PGMEA) (boiling point 146° C., δH: 9.9). The boiling point is a boiling point under atmospheric pressure.

The solvent (S2) preferably contains an alkylene glycol monoalkyl ether and an alkylene glycol monoalkyl ether acetate. The alkylene glycol monoalkyl ether and the alkylene glycol monoalkyl ether acetate are excellent in coating properties and drying properties, and easily form a homogeneous coating film by spin coating or the like. The alkylene glycol monoalkyl ether easily dissolves the impurity diffusing component (A). A content of the alkylene glycol monoalkyl ether is preferably 15% by mass or more and 45% by mass or less, and more preferably 25% by mass or more and 35% by mass or less with respect to a total mass of the alkylene glycol monoalkyl ether and the alkylene glycol monoalkyl ether acetate.

The content of the solvent (S1) is more than 0.10% by mass with respect to the mass of the solvent (S). When the diffusing agent composition contains, together with the impurity diffusing component (A) in an amount of more than 0% by mass and 1.0% by mass or less, the solvent (S1) and the solvent (S2) each having the above-described specific boiling point and δH in an amount such that the content of the solvent (S1) is more than 0.10% by mass with respect to the mass of the solvent (S), it is possible to prevent the generation of foreign matter (defects) in a coating film to be formed, as shown in Examples to be described later. The reason why the generation of foreign matter (defects) in the coating film to be formed can be prevented is unclear, but it is presumed to be due to the following mechanism.

When a diffusing agent composition containing no solvent (S1) and containing only the solvent (S2) as the solvent (S) is applied to form a coating film, the impurity diffusing component (A) dissolved in the solvent (S2) aggregates as the solvent (S2) volatilizes. The aggregate is presumed to be foreign matter (defects) generated in the coating film. This will be described by taking as an example a case of using a diffusing agent composition containing boric acid as the impurity diffusing component (A) and propylene glycol monomethyl ether (PGME) and propylene glycol monomethyl ether acetate (PGMEA) as the solvent (S). When the diffusing agent composition is applied to the semiconductor substrate by spin coating or the like to form a coating film, PGME volatilizes before PGMEA. This is because a boiling point of PGME is lower than a boiling point of PGMEA. The solubility of boric acid in PGME is higher than the solubility of boric acid in PGMEA. Hence, the boric acid dissolved in the volatilized PGME cannot be dissolved in PGMEA. The boric acid is a compound having three hydroxyl groups. Hence, the boric acid has a high δH, is easily hydrogen bonded, and is easily aggregated. Due to volatilization of PGME, which is capable of dissolving a large amount of boric acid, and ease of aggregation between boric acids, aggregates of boric acid are generated as foreign matter in the coating film. The diffusing agent composition containing two types of solvents, PGME and PGMEA, as the solvent (S) has been described above. Also, in the case of a diffusing agent composition containing only one type of solvent, PGME, as the solvent (S), similarly, due to volatilization of PGME, which is capable of dissolving a large amount of boric acid, and ease of aggregation between boric acids, the aggregates of boric acid are generated as foreign matter in the coating film.

The diffusing agent composition contains, as the solvent (S), a solvent (S1) of more than 0.10% by mass in addition to the solvent (S2). The boiling point of the solvent (S1) under atmospheric pressure is as high as 180° C. or higher, and δH of the solvent (S1) is as high as 14.0 or more. Hence, the solvent (S1) is difficult to volatilize, and the solubility of the impurity diffusing component (A) such as boric acid in the solvent (S) is relatively high. As a result, a state in which the impurity diffusing component (A) such as boric acid is dissolved is easily maintained. For this reason, it is presumed that the aggregation of the impurity diffusing component (A) such as boric acid can be prevented, and the generation of foreign matter in the coating film to be formed can be prevented.

On the other hand, when the diffusing agent composition does not contain the solvent (S1) or contains a small amount of the solvent (S1) of 0.10% by mass or less with respect to the mass of the solvent (S), a large amount of foreign matter is generated.

In the diffusing agent composition, the content of the solvent (S1) may be more than 0.10% by mass with respect to the mass of the solvent (S). From the viewpoint of further preventing the generation of foreign matter, the content of the solvent (S1) is preferably 0.20% by mass or more, and more preferably 5.0% by mass or more. In the diffusing agent composition, the content of the solvent (S1) may be less than 100% by mass with respect to the mass of the solvent (S). From the viewpoint of coating properties (performance of forming a thin coating film having a uniform film thickness), the content of the solvent (S1) is preferably less than 30% by mass, and more preferably 25% by mass or less.

### [Other Components]

The diffusing agent composition may include various additives such as a surfactant, a defoamer, a pH adjuster and a viscosity adjuster as long as desired effects are not impaired. The diffusing agent composition may contain a resin or a component that can become a resin in the coating film for the purpose of improving the coating properties or the like. The diffusing agent composition may not contain a resin or a component that can become a resin in the coating film. Even if the diffusing agent composition does not contain the resin or the like, a diffusing agent composition having excellent coating properties can be prepared. Examples of the resin include binder resins such as siloxane-based resins, acrylic resins, and polyvinyl alcohol-based resins. Examples of the component that can become a resin in the coating film include a hydrolyzable silane compound. The hydrolyzable silane compound is a compound having a functional group which generates a hydroxyl group by hydrolysis and which is bound to an Si atom. Examples of the hydrolyzable silane compound include tetraethoxysilane.

Predetermined amounts of the components described above are uniformly mixed, and thus the diffusing agent composition can be obtained.

### <<Method for Manufacturing Semiconductor Substrate>>

A method for manufacturing the semiconductor substrate preferably includes:
forming a coating film by applying the diffusing agent composition described above on the semiconductor substrate; and
diffusing the impurity diffusing component (A) in the diffusing agent composition into the semiconductor substrate. In the following description, the formation of the coating film is also referred to as a “coating step”, and the diffusion of the impurity diffusing component (A) into the semiconductor substrate is also referred to as a “diffusion step”. A pre-diffusion heating processing step of processing the semiconductor substrate including the coating film under a temperature condition lower than a diffusion temperature for a predetermined time may be performed between the coating step and the diffusion step.

### <Coating Step>

In the coating step, the diffusing agent composition described above is applied on the semiconductor substrate so as to form the coating film. The method of applying the diffusing agent composition is not particularly limited as long as the coating film having a desired film thickness can be formed. As the method of applying the diffusing agent composition, a spin coating method, an inkjet method and a spray method are preferable, and the spin coating method is particularly preferable. By forming a coating film using the diffusing agent composition described above, the generation of foreign matter can be prevented, and thus a coating film with less foreign matter can be formed.

The film thickness of the coating film formed of the diffusing agent composition is not particularly limited. The film thickness of the coating film is preferably 0.5 nm or more and 150 nm or less, and more preferably 1.0 nm or more and 5.0 nm or less. The film thickness of the coating film is an average value of film thicknesses of five or more points measured with an ellipsometer. By using the diffusing agent composition in which the content of the solvent (S1) is less than 30% by mass with respect to the mass of the solvent (S), a thin coating film having a uniform film thickness can be formed.

As the semiconductor substrate into which the impurity diffusing component (A) is diffused, various substrates that are conventionally used as targets into which an impurity diffusing component is diffused can be used without particular limitation. As the semiconductor substrate, a silicon substrate is typically used. Depending on the type of the impurity diffusing component (A) contained in the diffusing agent composition, the silicon substrate is selected as necessary from an n-type silicon substrate and a p-type silicon substrate. The semiconductor substrate such as the silicon substrate often includes a natural oxide film which is formed by natural oxidation of its surface. For example, the silicon substrate often includes a natural oxide film which is mainly formed of SiO₂. When the impurity diffusing component (A) is diffused into the semiconductor substrate, as necessary, an aqueous solution of hydrofluoric acid or the like is used to remove the natural oxide film on a surface of the semiconductor substrate.

The semiconductor substrate may have, on a surface to which the diffusing agent composition is applied, a three-dimensional structure including a convex portion and a concave portion. When the diffusing agent composition described above is used, even if the semiconductor substrate has such a three-dimensional structure, in particular, the semiconductor substrate has, on its surface, a three-dimensional structure including a nanoscale minute pattern, it is easy to uniformly form, for example, a thin coating film of 30 nm or less on the three-dimensional structure of the semiconductor substrate.

Although the shape of the pattern is not particularly limited, typical examples include a line in which a cross-sectional shape is rectangular and which is linear or curved, a groove and a hole.

The diffusing agent composition may be applied to the surface of the semiconductor substrate by a spin coating method or the like and then heated. The solvent can be removed by heating (drying). A heating temperature is preferably in a range of 50° C. or higher and 250° C. or lower, and more preferably in a range of 60° C. or higher and 200° C. or lower. A heat treatment time is preferably 5 seconds or more and 5 minutes or less, and more preferably 10 seconds or more and 3 minutes or less.

It is also preferable to apply the diffusing agent composition to the surface of the semiconductor substrate and to thereafter rinse the surface of the semiconductor substrate with an organic solvent. After the formation of the coating film, the surface of the semiconductor substrate is rinsed, and thus it is possible to make the film thickness of the coating film more uniform. In particular, when the semiconductor substrate has a three-dimensional structure on its surface, the film thickness of the coating film is easily increased in a bottom portion (step portion) of the three-dimensional structure. However, after the formation of the coating film, the surface of the semiconductor substrate is rinsed, and thus it is possible to make the film thickness of the coating film uniform.

As the organic solvent used for rinsing, the above-described organic solvent in which the diffusing agent composition may be contained can be used.

### [Pre-Diffusion Heating Processing Step]

In the pre-diffusion heating processing step, after the formation of the coating film until the start of the diffusion of the impurity diffusing component (A), heating processing is performed on the semiconductor substrate under the temperature condition lower than the diffusion temperature. The condition of the heating processing described above is preferably 450° C. or higher and lower than 700° C. for 5 seconds or more and 1 minute or less. The pre-diffusion heating processing is preferably performed at a constant temperature.

When the semiconductor substrate including the coating film is processed under the temperature condition lower than the diffusion temperature for the predetermined time, depending on the type of the impurity diffusing component (A), it is likely that the sublimation of the impurity diffusing component (A) is reduced and that the diffusion properties (such as in-plane uniformity and a resistance value) of the impurity diffusing component (A) can be enhanced. The performance of the pre-diffusion heating processing step is effective particularly when the impurity diffusing component (A) is a boron compound. It can be considered that boron in the impurity diffusing component (A) is oxidized into borate glass and that thus boron is easily fixed as a film.

For example, the preferred temperature in the pre-diffusion heating processing is preferably 450° C. or higher and lower than 700° C., more preferably 500° C. or higher and 690° C. or lower, and particularly preferably 500° C. or higher and 670° C. or lower.

In terms of a balance between the effect of enhancing the impurity diffusion property in the pre-diffusion heating processing step and the manufacturing efficiency of the semiconductor substrate, the heating processing time in the pre-diffusion heating processing is preferably 5 seconds or more and 45 seconds or less and more preferably 10 seconds or more and 30 seconds or less.

### [Diffusion Step]

In the diffusion step, the impurity diffusing component (A) in the coating film which is formed of the diffusing agent composition on the semiconductor substrate is diffused into the semiconductor substrate. Examples of the method of diffusing the impurity diffusing component (A) into the semiconductor substrate include a method of diffusing, by heating, the impurity diffusing component (A) from the coating film formed of the diffusing agent composition. In the specification of the present application, the “diffusion step” is assumed to be a step which is performed after the time when the predetermined diffusion temperature is reached until a diffusion time (holding time of the diffusion temperature) elapses.

As a typical method, a method of heating, in a heating furnace such as an electric furnace, the semiconductor substrate including the coating film formed of the diffusing agent composition is mentioned. In this case, a heating condition is not particularly limited as long as the impurity diffusing component (A) is diffused to a desired degree.

The heating for the diffusion of the impurity diffusing component (A) is performed, at a temperature which is preferably 700° C. or higher and 1400° r or lower and is more preferably 700° C. or higher and lower than 1200° C., preferably for 1 second or more and 20 minutes or less and more preferably for 1 second or more and 1 minute or less.

When the temperature of the semiconductor substrate can be rapidly increased at a temperature increase rate of 25° C./second or more to the predetermined diffusion temperature, the diffusion time (holding time of the diffusion temperature) may be 30 seconds or less, 10 seconds or less, 5 seconds or less, 3 seconds or less, 2 seconds or less or a very short time such as less than 1 second. A lower limit of the diffusion time is not particularly limited as long as the impurity diffusing component can be diffused to a desired degree. For example, the lower limit of the diffusion time may be 0.05 seconds or more, 0.1 seconds or more, 0.2 seconds or more, 0.3 seconds or more or 0.5 seconds or more. In this case, in a shallow region of the surface of the semiconductor substrate, the impurity diffusing component (A) is easily diffused at a high concentration.

In the diffusion step, an atmosphere around the semiconductor substrate when the semiconductor substrate is heated is preferably an atmosphere in which an oxygen concentration is 1% by volume or less. The oxygen concentration in the atmosphere is more preferably 0.5% by volume or less, still more preferably 0.3% by volume or less, and particularly preferably 0.1% by volume or less, and most preferably, oxygen is not contained. The oxygen concentration in the atmosphere is adjusted to a desired concentration at any timing in the step preceding the diffusion step. A method of adjusting the oxygen concentration is not particularly limited. Examples of the method of adjusting the oxygen concentration include a method of passing an inert gas such as nitrogen gas into a device for heating the semiconductor substrate and discharging oxygen inside the device to the outside of the device together with the inert gas. In this method, the time during which the inert gas is passed is adjusted, and thus it is possible to adjust the oxygen concentration inside the device. As the time during which the inert gas is passed is increased, the oxygen concentration inside the device is lowered. When the diffusion is performed in an atmosphere with a low oxygen concentration, it can be considered that silicon oxide formed by oxygen on the surface of the semiconductor substrate is unlikely to be formed. Consequently, the impurity diffusing component (A) is easily diffused into the substrate which is mainly formed of silicon, and thus the in-plane uniformity of diffusion of the impurity diffusing component (A) is enhanced.

After the diffusion step described above, on the surface of the semiconductor substrate into which the impurity diffusing component (A) is diffused and in the vicinity of the surface, a residue derived from the impurity diffusing component (A) may be adhered or a high-concentration layer which includes the impurity diffusing component at an extremely high concentration may be formed. The adherence of the residue and the formation of the high-concentration layer may adversely affect the function of a semiconductor device when the semiconductor device is manufactured with the semiconductor substrate obtained through the diffusion step. Hence, after the diffusion step, processing for removing the residue and the high-concentration layer is preferably performed.

As the preferred processing after the diffusion step, processing which brings a hydrofluoric acid (HF) aqueous solution into contact with the surface of the semiconductor substrate is mentioned. In the processing described above, the residue adhered to the surface of the semiconductor substrate can be removed. A concentration of the hydrofluoric acid aqueous solution is not particularly limited as long as the residue can be removed. For example, the concentration of the hydrofluoric acid aqueous solution is preferably 0.05% by mass or more and 5% by mass or less, and more preferably 0.1% by mass or more and 1% by mass or less. The temperature at which the hydrofluoric acid aqueous solution is brought into contact with the surface of the semiconductor substrate is not particularly limited as long as the residue can be removed. For example, the temperature at which the hydrofluoric acid aqueous solution is brought into contact with the surface of the semiconductor substrate is preferably 20° C. or higher and 40° C. or lower and more preferably 23° C. or higher and 30° C. or lower. The time during which the hydrofluoric acid aqueous solution is brought into contact with the surface of the semiconductor substrate is not particularly limited as long as the residue can be removed and unacceptable damage is prevented from occurring in the semiconductor substrate. For example, the time during which the hydrofluoric acid aqueous solution is brought into contact with the surface of the semiconductor substrate is preferably 15 seconds or more and 5 minutes or less and is more preferably 30 seconds or more and 1 minute or less.

Before the processing which brings the hydrofluoric acid aqueous solution into contact, plasma ashing is preferably performed on the surface of the semiconductor substrate. In the processing described above, not only the reside but also the high-concentration layer formed on the surface of the semiconductor substrate or in the vicinity of the surface of the semiconductor substrate can be removed. As the plasma ashing, plasma ashing using an oxygen-containing gas is preferable, and oxygen plasma ashing is more preferable. As long as the desired effects are not impaired, various gases which are conventionally used in plasma processing together with oxygen can be mixed with the gas which is used for generation of oxygen plasma. Examples of the gas described above include nitrogen gas, hydrogen gas and the like. The conditions of the plasma ashing are not particularly limited as long as desired effects are not impaired.

According to the method described above, a coating film in which generation of foreign matter is prevented can be formed using the diffusing agent composition. Hence, it is possible to reduce a bad influence of the foreign matter on the semiconductor element. Therefore, a semiconductor element having high reliability can be manufactured. The method described above can be suitably applied to the manufacturing of a CMOS element for a CMOS image sensor and a semiconductor element such as a logic LSI device.

### EXAMPLES

Although the present invention will be more specifically described below using Examples, the present invention is not limited to Examples below.

### Examples 1 to 4 and Comparative Examples 3 to 5

In Examples 1 to 4 and Comparative Examples 1 to 5, as the impurity diffusing component (A), A1 below was used.
A1: boric acid

In Examples 1 to 4 and Comparative Examples 1 to 5, as the amine compound (B), B1 below was used.
B1: N,N′-bis (3-aminopropyl) ethylenediamine (NA: 2, NB: 2, NC: 0)

In Examples 1 to 4 and Comparative Examples 1 to 5, as the solvent (S), S1 and S2 below were used. The following boiling point of the solvent (S) is a boiling point under atmospheric pressure. The following δH of the solvent (S) was calculated using software (software name: Hansen Solubility Parameter in Practice (HSPiP)).

### <S1>

S1-1: Diethylene glycol (boiling point 245° C., δH: 19.0)
S1-2: Ethylene glycol (boiling point 198° C., δH: 26.0)
S1-3: 1,5-pentadiol (boiling point 239° C., δH: 18.9)

### <S2>

S2-1: propylene glycol monomethyl ether acetate (PGMEA) (boiling point 146° C., δH: 9.8)
S2-2: propylene glycol monomethyl ether (PGME) (boiling point 121° C., δH: 11.6)
S2-3: 2-pyrolidone (boiling point 245° C., δH: 9.0)
S2-4: benzyl alcohol (boiling point 200° C., δH: 13.7)
S2-5: Ethanol (boiling point 78° C., δH: 19.4)

### [Production of Diffusing Agent Composition]

The diffusing agent compositions of Examples 1 to 4 and Comparative Examples 1 to 2 were prepared by mixing A1 in such an amount that the content in the diffusing agent composition was 0.080% by mass, B1 in such an amount that the content in the diffusing agent composition was 0.045, by mass, the solvent (S1) of the type shown in Table 1 in such an amount that the content in the diffusing agent composition was the content shown in Table 1, and S2-1 and S2-2 in such an amount that the content in the diffusing agent composition was the content shown in Table 1, and dissolving the impurity diffusing component (A) and the amine compound (B) in the solvent (S). The diffusing agent compositions of Comparative Examples 3 to 5 were prepared by mixing A1 in such an amount that the content in the diffusing agent composition was 0.080% by mass, B1 in such an amount that the content in the diffusing agent composition was 0.045% by mass, a comparative solvent of the solvent (S1) of the type shown in Table 1 in such an amount that the content in the diffusing agent composition was the content shown in Table 1, and S2-1 and S2-2 in such an amount that the content in the diffusing agent composition was the content shown in Table 1, and dissolving the impurity diffusing component (A) and the amine compound (B) in the solvent (S). In Comparative Examples 3 to 5, the solvent S1 was not mixed. The content (% by mass) of the solvent (S1) relative to the mass of solvent (S) is shown in the column “S1/(S1+S2)×100” in Table 1.

### [Evaluation of Foreign Matter (Defects) of Coating Film]

The diffusing agent compositions of Examples 1 to 4 and Comparative Examples 2 to 5 each were applied to a surface of a silicon substrate (12 inches, n-type) having a flat surface with a spin coater at a rotation speed of 2000 rpm, and heated at 100° C. for 60 seconds to form a coating film. A surface of the formed coating film was inspected with a wafer inspection device (manufactured by KLA Tencor Corporation, product name “Surfscan SP2”) to determine the number of foreign matters of 0.1 μm or more (defect count). The results are shown in Table 2.

### (Evaluation of Coating Properties)

Coating films were formed in the same manner as in [Evaluation of foreign matter (defects) of coating film] using the diffusing agent compositions of Examples 1 to 4 and Comparative Examples 1 to 2 except that a silicon substrate (6 inches, n-type) having a flat surface was used instead of the silicon substrate (12 inches, n-type) having a flat surface. The film thickness of the formed coating film was measured at five points using an ellipsometer, and the average film thickness and standard deviation were calculated. The results are shown in Table 2.

TABLE 1

| | Solvent (S) | | | | | | |
|---|---|---|---|---|---|---|---|
| | | | S2 | | | | |
| | | | COMPARATIVE | | | | |
| | S1 | | SOLVENT OF S1 | | S2-1 | S2-2 | S1/ |
| | | Content | | Content | Content | Content | (S1 + S2) × |
| | Type | [% by mass] | Type | [% by mass] | [% by mass] | [% by mass] | 100 |
| Example 1 | S1-1 | 0.90 | — | — | 69.28 | 29.69 | 0.9 |
| Example 2 | S1-1 | 10.00 | — | — | 62.91 | 26.96 | 10 |
| Example 3 | S1-2 | 1.00 | — | — | 69.21 | 29.66 | 1.0 |
| Example 4 | S1-3 | 0.90 | — | — | 69.28 | 29.69 | 0.9 |
| Comparative | S1-1 | 99.88 | — | — | 0.00 | 0.00 | 100 |
| Example 1 | | | | | | | |
| Comparative | S1-1 | 0.10 | — | — | 69.84 | 29.93 | 0.1 |
| Example 2 | | | | | | | |
| Comparative | — | — | S2-3 | 1.00 | 69.21 | 29.66 | — |
| Example 3 | | | | | | | |
| Comparative | — | — | S2-4 | 0.90 | 69.28 | 29.69 | — |
| Example 4 | | | | | | | |
| Comparative | — | — | S2-5 | 0.90 | 69.28 | 29.69 | — |
| Example 5 | | | | | | | |

TABLE 2

| | Foreign Matter | Coating Property | | Diffusion |
|---|---|---|---|---|
| | Evaluation | Evaluation | | Evaluation |
| | Number of | Average | | Sheet |
| | Foreign | Film | Standard | Resistance |
| | Matters | Thickness | Deviation σ | Value |
| | [piece] | [nm] | [nm] | [Ω/sq.] |
| Example 1 | 37 | 3.4 | 0.05 | 314.5 |
| Example 2 | 17 | 3.4 | 0.05 | 309.4 |
| Example 3 | 279 | 3.4 | 0.05 | 320.6 |
| Example 4 | 38 | 3.4 | 0.04 | 319.3 |
| Comparative | — | 121.3 | 78.40 | — |
| Example 1 | | | | |
| Comparative | 44152 | 3.4 | 0.06 | — |
| Example 2 | | | | |
| Comparative | 8608 | — | — | — |
| Example 3 | | | | |
| Comparative | 5114 | — | — | — |
| Example 4 | | | | |
| Comparative | 8692 | — | — | — |
| Example 5 | | | | |

According to Table 1 and Table 2, it can be seen that it is possible to prevent the generation of foreign matter in a coating film to be formed when a diffusing agent composition including an impurity diffusing component (A) and a solvent (S) was used, in which a content of the impurity diffusing component (A) is more than 0% by mass and 1.0% by mass or less, the solvent (S) includes a solvent (S1) and a solvent (S2) different from the solvent (S1), a boiling point of the solvent (S1) under atmospheric pressure is 180° C. or higher, a hydrogen bonding force term δH of a Hansen solubility parameter of the solvent (S1) is 14.0 or more, and a content of the solvent (S1) is more than 0.10% by mass with respect to a mass of the solvent (S). In addition, it can be seen that in Examples 1 to 4 in which the content of the solvent (S1) is more than 0.10% by mass and less than 30% by mass with respect to the mass of the solvent (S), the coating properties are excellent and a thin and uniform film can be formed.

On the other hand, it can be seen that when the solvent (S1) is not contained, or when the solvent (S1) is contained, but the content of the solvent (S1) is 0.10% by mass or less with respect to the mass of the solvent (S), a large amount of foreign matter is generated.

### [Manufacturing of Semiconductor Substrate] Diffusion

After a coating film was formed in the same manner as in [Evaluation of foreign matter (defects) of coating film] using the diffusing agent compositions of Examples 1 to 4, an impurity diffusing component was diffused in accordance with the following method. With a rapid thermal anneal device (lamp anneal device), under a nitrogen atmosphere at a flow rate of 1 L/m, at a temperature increase rate of 15° C./second, the semiconductor substrate including the coating film was heated to 1000° C. and held at 1000° C. for 25 seconds to perform diffusion processing. The starting point of the diffusion time was the time when the temperature of the substrate reached 1000° C. After the completion of the diffusion, the semiconductor substrates were rapidly cooled to room temperature.

The results of measurements of sheet resistance values of the semiconductor substrates after the diffusion processing are described in table 2. In any of Examples in which the diffusion processing was performed, after the diffusion processing, the semiconductor substrates were inverted from the n-type to the p-type.

1. A diffusing agent composition for use in diffusing an impurity into a semiconductor substrate, the diffusing agent composition comprising:
an impurity diffusing component (A); and a solvent (S),
wherein a content of the impurity diffusing component (A) is more than 0% by mass and 1.0% by mass or less,
wherein the solvent (S) comprises a solvent (S1) and a solvent (S2) which is different from the solvent (S1),
a boiling point of the solvent (S1) under atmospheric pressure is 180° C. or higher,
a hydrogen bonding force term δH of a Hansen solubility parameter of the solvent (S1) is 14.0 or more, and
a content of the solvent (S1) is more than 0.10% by mass with respect to a mass of the solvent (S).

2. The diffusing agent composition according to claim 1, wherein the impurity diffusing component (A) is 60% by mass or more with respect to a total solid content in the diffusing agent composition.

3. The diffusing agent composition according to claim 1, wherein the content of the solvent (S1) is less than 30% by mass with respect to the mass of the solvent (S).

4. The diffusing agent composition according to claim 1, wherein the solvent (S1) is a glycol-based solvent.

5. The diffusing agent composition according to claim 1, wherein the impurity diffusing component (A) comprises a compound having the hydrogen bonding force term δH of the Hansen solubility parameter of 60.0 or more.

6. The diffusing agent composition according to claim 1, further comprising an amine compound (B).

7. A method for manufacturing a semiconductor substrate, the method comprising: forming a coating film by applying the diffusing agent composition according to claim 1 on the semiconductor substrate; and
diffusing the impurity diffusing component (A) in the diffusing agent composition into the semiconductor substrate.

8. The method for manufacturing a semiconductor substrate according to claim 7, wherein the coating film is heated to diffuse the impurity diffusing component (A) into the semiconductor substrate.
